(19) United States
(12) Patent Application Publication
(10) Pub. No.: US 2025/0287806 A1
(43) Pub. Date: Sep. 11, 2025

(54) LIGHT EMITTING DISPLAY DEVICE

(71) Applicant: LG Display Co., Ltd., Seoul (KR)

(72) Inventors: Bo Seong KIM, Paju-si, Gyeonggi-do (KR); Moon Sung KIL, Paju-si, Gyeonggi-do (KR); Kwang Jong KIM, Paju-si, Gyeonggi-do (KR)

(73) Assignee: LG Display Co., Ltd., Seoul (KR)

(21) Appl. No.: 18/270,047

(22) PCT Filed: Oct. 28, 2021
(86) PCT No.: PCT/KR2021/015327

§ 371 Date: Jun. 28, 2023

(30) Foreign Application Priority Data
Dec. 29, 2020 (KR) 10-2020-0186850

(51) Int. Cl. H10K 59/35; H10K 59/38; H10K 59/80

(52) U.S. Cl. CPC H10K 59/351; H10K 59/353; H10K 59/38; H10K 59/8792

(57) ABSTRACT

Disclosed is a light emitting display device configured such that the upper structure of a light emitting element is changed and thus a polarizer is omitted, thereby increasing color gamut, reducing power consumption, and reducing a decrease in luminance due to a change in viewing angle.

### TECHNICAL FIELD

The present disclosure relates to a display device, and more particularly to a light emitting display device configured such that the upper structure of a light emitting element is changed, thereby increasing color gamut, reducing power consumption, and reducing a decrease in luminance due to a change in viewing angle.

### BACKGROUND ART

With recent approach to a full-scale information age, displays capable of visually expressing electrical information signals have been rapidly developed. Correspondingly, various display devices having excellent performance, such as slimness, light weight, and low power consumption, have been developed and have rapidly replaced a conventional cathode ray tube (CRT).

Among the display devices, a light emitting display device having a light emitting element in a display panel has been considered as a competitive application in order to achieve compaction of the device and vivid color display without necessity of a separate light source.

### DISCLOSURE

### Technical Problem

A light emitting display device includes light emitting elements, which are configured to emit light, provided in a display panel. Each light emitting element is designed so as to be optimized for front emission. As a result, a viewing angle is changed, and luminance is reduced.

It is an object of the present disclosure to provide a light emitting display device capable of preventing a decrease in luminance due to a change in viewing angle.

### Technical Solution

A light emitting display device according to the present disclosure is configured such that the structure outside light emitting elements of subpixels that emit the same color of light is changed, thereby increasing color gamut, reducing power consumption, and reducing a decrease in luminance due to a change in viewing angle.

A light emitting display device according to an embodiment of the present disclosure includes first subpixels and second subpixels provided on a substrate so as to be spaced apart from each other, each of the first subpixels and the second subpixels being configured to emit a first color of light, third subpixels and fourth subpixels spaced apart from the first and second subpixels, each of the third subpixels being configured to emit a second color of light different from the first color of light, each of the fourth subpixels being configured to emit a third color of light different from the first color of light, a first color filter provided at each of the first subpixels, the first color filter being configured to transmit the first color of light emitted from the first subpixel while having a first peak, a second color filter provided at each of the second subpixels, the second color filter being configured to transmit the first color of light emitted from the second subpixel while having a second peak having a longer wavelength than the first peak, and third and fourth color filters provided respectively at the third and fourth subpixels, the third and fourth color filters being configured to respectively transmit the third color of light and the fourth color of light.

A light emitting display device according to another embodiment of the present disclosure includes first light emitting elements and second light emitting elements provided on a substrate so as to be spaced apart from each other, each of the light emitting elements and the second light emitting elements being configured to emit a first color of light, third light emitting elements and fourth light emitting elements spaced apart from the first and second light emitting elements, each of the third light emitting elements being configured to emit a second color of light different from the first color of light, each of the fourth light emitting elements being configured to emit a third color of light different from the first color of light, first to fourth transistors connected respectively to the first to fourth light emitting elements, a first color filter provided on the first light emitting elements, the first color filter being configured to transmit the first color of light while having a first peak, a second color filter provided on the second light emitting elements, the second color filter being configured to transmit the first color of light while having a second peak having a longer wavelength than the first peak, and third and fourth color filters provided on the third and fourth light emitting elements, the third and fourth color filters being configured to respectively transmit the third color of light and the fourth color of light.

### Advantageous Effects

The light emitting display device according to the present disclosure has the following effects.

First, color filters capable of preventing reflection of external light may be further provided above light emitting elements on a substrate, whereby it is possible to omit a polarizer, and therefore it is possible to increase color gamut and to reduce power consumption.

Second, in the light emitting display device according to the present disclosure described above, in correspondence between color filters and light emitting elements that emit light having wavelengths transmitted through the color filters, light emitting elements that emit at least one color of light are divided into two parts, and first and second color filters having transmittance for light having different peaks are applied thereto, whereby it is possible to prevent or alleviate a phenomenon in which luminance is reduced depending on a change in viewing angle.

Third, a structure in which different color filters having different peak transmittances correspond to first and second light emitting elements alternately disposed so as to emit the same color of light is applied. In this structure, percentage in emission through the color filter having relatively short-wavelength transmittance during low-gradation driving may be increased, whereby negative shift to the short wavelength is achieved, and therefore it is possible to prevent visibility due to other color emission during low-gradation driving.

### DESCRIPTION OF DRAWINGS

FIG. 1 is a plan view showing a light emitting display device according to a first embodiment of the present disclosure.

FIG. 2 is a sectional view showing a light emitting element provided in each of first and second subpixels of FIG. 1.

FIG. 3 is a sectional view taken along line I-I′ of FIG. 1.

FIG. 4 is a graph showing transmission characteristics of a first color filter and a second color filter of the light emitting display device according to the present disclosure and effects in transmission characteristics of the first and second color filters due to 1:1 disposition thereof.

FIG. 5 is a plan view showing a light emitting display device according to a second embodiment of the present disclosure.

FIG. 6 is a graph showing white luminance based on a viewing angle when a polarizer is applied to an upper side of an emission portion and when a color filter is applied to the upper side of the emission portion.

FIG. 7 is a graph showing a change in luminance depending on the viewing angle in first to fourth experimental examples.

FIG. 8A is a graph showing light intensity depending on wavelength when a green subpixel emits low-gradation light in the first experimental example.

FIG. 8B is a graph showing a change in CIEx of the green subpixel depending on gradation in the first experimental example.

FIG. 9 is a graph showing transmission characteristics of each of first and second color filters according to the present disclosure and transmission characteristics of the first and second color filters when disposed on a substrate at a ratio of 1:1.

FIG. 10 is a graph showing light intensity depending on wavelength when each of first and second subpixels according to the present disclosure emits low-gradation light and when both the first and second subpixels emit low-gradation light.

### BEST MODE

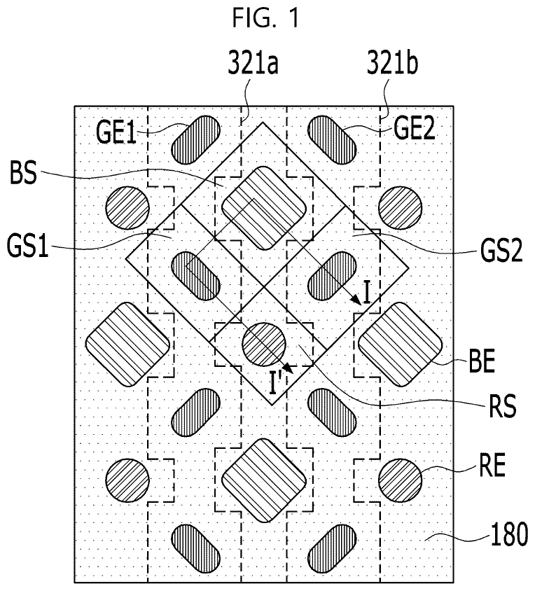

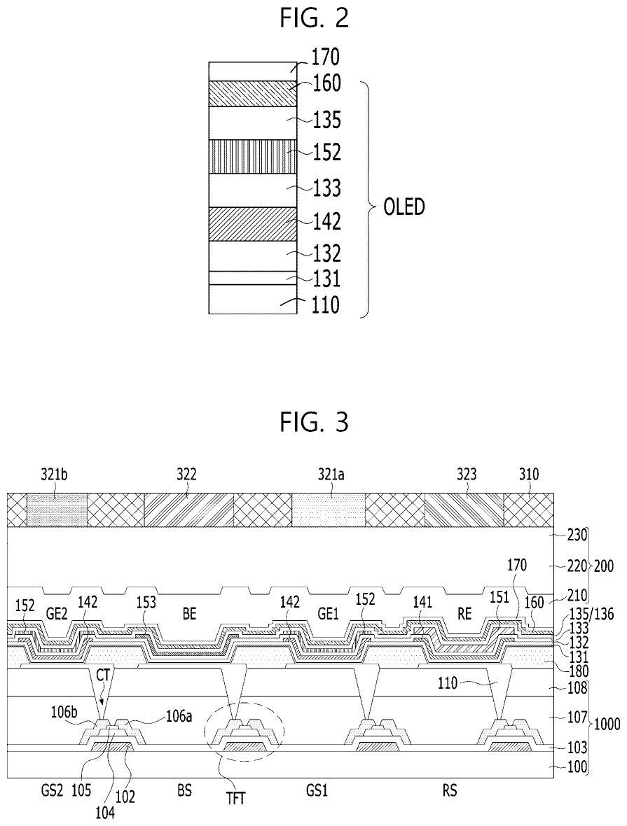

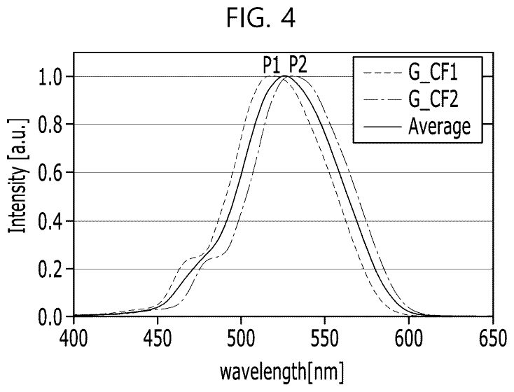

FIG. 1 is a plan view showing a light emitting display device according to a first embodiment of the present disclosure, and FIG. 2 is a sectional view showing a light emitting element provided in each of first and second subpixels of FIG. 1. FIG. 3 is a sectional view taken along line I-I′ of FIG. 1. In addition, FIG. 4 is a graph showing transmission characteristics of a first color filter and a second color filter of the light emitting display device according to the present disclosure and effects in transmission characteristics of the first and second color filters due to 1:1 disposition thereof.

As shown in FIGS. 1 and 2, the light emitting display device according to the first embodiment of the present disclosure includes first subpixels GS1 and second subpixels GS2 provided on a substrate 100 so as to be spaced apart from each other, each of the first subpixels and the second subpixels being configured to emit a first color of light, third subpixels BS and fourth subpixels RS spaced apart from the first and second subpixels GS1 and GS2, each of the third subpixels being configured to emit a second color of light, which is different from the first color of light, each of the fourth subpixels being configured to emit a third color of light, which is different from the first color of light, a first color filter 321a provided at each of the first subpixels GS1, the first color filter being configured to transmit the first color of light emitted from the first subpixel GS1 while having a first peak, a second color filter 321b provided at each of the second subpixels GS2, the second color filter being configured to transmit the first color of light emitted from the second subpixel GS2 while having a second peak, which has a longer wavelength than the first peak, and third and fourth color filters 322 and 323 provided respectively at the third and fourth subpixels BS and RS, the third and fourth color filters being configured to respectively transmit the third color of light and the fourth color of light.

In the light emitting display device according to the present disclosure, as shown in FIG. 4, the first subpixel GS1 and the second subpixels GS2, which emit the same color of light, have different transmittances, wherein a first color filter G_CF1 (321a of FIG. 3) and a second color filter G_CF2 (321b of FIG. 3) are provided, whereby peaks of light finally transmitted through the first and second subpixels GS1 and GS2 are different from each other. Here, a second peak P2 of the second color filter 321b has a longer wavelength than a first peak P1 of the first color filter 321a. When the first and second color filters 321a and 321b, which are different from each other, are applied, there is an effect in that full width at half maximum of light emitted from both the first and second subpixels GS1 and GS2 is greater than full width at half maximum of each of the first and second color filters 321a and 321b, as expressed by Average in FIG. 4, compared to when a single color filter is applied. In addition, an increase in full width at half maximum may compensate for luminance, whereby it is possible to prevent or alleviate a decrease in luminance due to a change in viewing angle.

A polarizer reduces transmittance of light emitted from a light emitting element in all wavelengths by half. In a structure in which the polarizer is used, therefore, power consumption must be increased in consideration of transmittance of light reduced by half by the polarizer. In contrast, in the light emitting display device according to the present disclosure, each of the first to fourth color filters 321a, 321b, 322, and 323 is transmissive to a specific wavelength. Consequently, transmittance of color light emitted from the light emitting element of each subpixel may be increased, whereby color gamut may be increased, and current necessary to turn on the light emitting element may be reduced, compared to the structure in which the polarizer is provided, whereby power consumption may be reduced.

It is advantageous that the peak difference (P2−P1) between the first and second color filters 321a and 321b is greater, since full width at half maximum is further increased; however, the first and second subpixels GS1 and GS2 in which the first and second color filters 321a and 321b are disposed must emit the same color of light without sense of difference. For this reason, the peak difference (P2−P1) of light transmitted through the first and second color filters 321a and 321b may be 20 nm or less. In addition, it was confirmed through the following experiments that, when the peak difference between the first and second color filters 321a and 321b was about 4 nm or more, a decrease in luminance due to a change in viewing angle was meaningfully alleviated. That is, when the difference between the first and second peaks of the first and second color filters 321a and 321b according to the present disclosure is 4 nm to 20 nm, it is possible to maintain emission characteristics of the same color of light and to reduce a decrease in luminance due to a change in viewing angle.

At time, the first peak P1, which has a relatively short wavelength, may have a wavelength of 510 nm to 550 nm, and the second peak P2 may have a wavelength of 514 nm to 570 nm. In any case, the second peak P2 has a longer wavelength than the first peak P1.

As shown in FIG. 1, the first and second color filters 321a and 321b may be parallel to each other, and may be disposed so as not to overlap emission portions BE and RE of the third and fourth subpixels BS and RS. In this case, when the first and second color filters 321a and 321b are disposed long in a vertical direction, as shown in FIG. 1, each of the first and second color filters 321a and 321b may have a relatively large width in an area in which the first and second emission portions GE1 and GE2, which are long in a diagonal direction, and may have a small width so as not to neighbor the blue emission portion BE and the red emission portion RE in an area in which the first and second emission portions GEL and GE2 are located in a horizontal direction. In addition, the first and second color filters 321a and 321b may be vertically parallel to each other, as shown in FIG. 1, or may be horizontally parallel to each other, depending on circumstances. Depending on circumstances, the first and second color filters may be parallel to each other in the diagonal direction depending on diagonal disposition of the first and second emission portions GE1 and GE2.

In the light emitting display device according to the present disclosure, the subpixel having the first and second color filters 321a and 321b having different transmittances applied thereto is a green subpixel as an example. The reason for this is that green emission greatly contributes to expression of white light, and therefore the number of green subpixels is increased. When the light emitting display device has a structure in which the number of other color subpixels is increased, the color subpixels disposed at a relatively higher percentage may be divided into two groups, to which different color filters configured to have transmittances having a peak a difference within predetermined wavelength may be applied, whereby it is possible to improve luminance depending on a change in viewing angle for the color.

An example in which the green emission portions are denoted by GEL and GE2, the blue emission portion is denoted by BE, and the red emission portion is denoted by RE in arrangement of the subpixels shown in FIG. 1 will be briefly described.

The first subpixel GS1 includes the first green emission portion GEL and a part of a bank 180 therearound, and the second subpixel GS2 includes the second green emission portion GE2 and a part of the bank 180 therearound. In addition, the third subpixel BS includes the blue emission portion BE and a part of the bank 180 therearound, and the fourth subpixel RS includes the red emission portion RE and a part of the bank 180 therearound.

It is preferable for the first and second green emission portion GE1 and GE2 to have the same size and the same shape in order to achieve a symmetrical and supplementary effect.

The blue emission portion BE and the red emission portion RE may have the same shape as the first and second green emission portions GEL and GE2; however, the shape and size thereof may be adjusted in consideration of the efficiency, lifespan characteristics, and transmittance of each emission portion.

In the example shown, each of the first and second green emission portions GEL and GE2 is disposed long in the diagonal direction, wherein opposite ends thereof are rounded, the blue emission portion BE is formed in an appropriate diamond shape, wherein each vertex of the diamond shape is rounded, and the red emission portion RE is circular. However, this is an example, and change to other shapes is possible.

As shown FIG. 1, the first and second subpixels GS1 and GS2 respectively having the first and second green emission portions GE1 and GE2 may be alternately disposed in a row or a column.

In this case, the first subpixels GS1 and the second subpixels GS2 may be disposed side by side, and the third subpixels BS and the fourth subpixels RS are disposed in parallel to the first subpixels GS1 while being alternately disposed between the first and second subpixels GS1 and GS2 that are disposed side by side while being adjacent to each other.

The first to fourth subpixels GS1, GS2, BS, and RS may be repeatedly disposed in an imaginary diamond shape.

Meanwhile, the emission portions GE1, GE2, BE, and RE of the first to fourth subpixels GS1, GS2, BS, and RS are surrounded by the bank 180, whereby the areas thereof are defined.

The sectional construction of the light emitting display device according to the present disclosure will be described in detail with reference to FIGS. 2 and 3.

In FIG. 3, a light emitting element OLED located at each of the emission portions GE1, GE2, BE, and RE may include an anode 110, a cathode 160, and an organic stack located between the anode 110 and the cathode 160.

Each emission portion GE1, GE2, BE, or RE may include at least one emission layer 152, 152, 153, or 151, as the minimum construction, a common layer under the emission layer, and a common layer above the emission layer. In addition to the common layers, an optical compensation layer configured to selectively adjust optical distance from a specific emission portion or an adjustment layer having a hole blocking function or an electron blocking function may be further included.

FIG. 2 shows the construction of an organic stack according to an example.

The construction of the first subpixel GS1 and the second subpixel GS2 will be described with reference to FIG. 2.

An organic stack including a hole injection layer 131, a hole transport layer 132, a first hole transport assistance layer 142, an electron blocking layer 133, a green emission layer 152, and an electron transport layer 135 sequentially arranged may be provided on a first anode 110. In addition, an electron injection layer 136 is provided on the electron transport layer 135, and a cathode 160 is provided on the electron injection layer 136.

The electron injection layer 136, which directly abuts the cathode 160, may include an inorganic dopant or may be made of only an inorganic material. Consequently, the electron injection layer may be a component of the cathode 160. The electron injection layer 136 may be formed together with the cathode 160 in the previous step of the cathode 160. That is, the electron injection layer 136 and the cathode 160 may be continuously formed in the same chamber in the state in which only materials that are supplied are different from each other.

In the organic stack, the hole injection layer 131, the electron blocking layer 133, a hole blocking layer 134, and the electron transport layer 135 are common layers formed irrespective of subpixels excluding that the first hole transport assistance layer 142, which is provided to adjust optical distance from the green emission portion, is optionally formed in the first and second subpixels GS1 and GS2. In addition, the electron injection layer 136 and the cathode 160 formed on the electron transport layer 135 are common layers formed irrespective of subpixels. The common layer may be formed without a mask having microscopic openings, such as a fine metal mask (FMM), and is a layer formed integrally so as to cover all subpixels provided in a display area of the substrate 100.

Meanwhile, FIG. 2 shows that the light emitting element has a single organic stack; however, the present disclosure is not limited thereto, and the light emitting element may have a plurality of stacks.

The green emission layer 152 of each of the first and second subpixels GS1 and GS2 may include a green host gh and a green dopant gd. The green host gh may include a plurality of different hosts. Examples of the green host gh may include C-545T (10-(2-benzothia-zylyl)-1,1,7,7-tetramethyl-2,3,6,7-tetrahydro-1H, 5H, 11H-[1]benzo-pyrano [6,7,8-ij]quinolizin-11-one) using Alq3 as a matrix, derivatives thereof, quinacridone derivatives, and carbazole derivatives. When Alq3 is used as the host, green emission is possible; however, another green dopant may be included in order to improve green emission efficiency.

The third subpixel BS has no hole transport assistance layer, unlike the first and second subpixels GS1 and GS2 and the fourth subpixel RS. Hole transport assistance layers 141 and 142 are provided to adjust different optical distances from different color emission layers. Since an emission area is formed at a relatively short distance from the anode 110, the third subpixel BS, which emits blue light, has no hole transport assistance layer.

In the blue subpixel BS, the light emitting element has a stacking sequence of an anode 110, a hole injection layer 131, a hole transport layer 132, an electron blocking layer 133, a blue emission layer 153, a hole blocking layer 134, an electron transport layer 135, an electron injection layer 136, and a cathode 160.

The blue emission layer 153 may include at least one blue host and at least one blue dopant. Specifically, the blue emission layer may be formed by doping at least one fluorescent host material selected from the group consisting of an anthracene derivative, a pyrene derivative, and a perylene derivative with a pyrene-based or boron-based fluorescent blue dopant. When a phosphorescent blue material stable as a blue dopant is developed, replacement may be possible.

Each of the first and second subpixels GS1 and GS2, in which the distance between the optimum emission area in the emission layer and the anode 110 is large, compared to the blue subpixel BS, has a first hole transport assistance layer 142, and the red subpixel RS has a second hole transport assistance layer 141. Since optical distances of red and green colors are different from each other, there may be a difference in thickness between the first hole transport assistance layer 142 and the second hole transport assistance layer 141. In addition, it is possible to adjust optical distance of each emission layer through the thickness difference between the emission layers 152, 153, and 151. Depending on circumstances, different hole transport assistance layers and emission layers having different thicknesses may be applied to respective color pixels.

The fourth subpixel RS is different from the first and second subpixels GS1 and GS2 in that a second hole transport assistance layer 141 and a red emission layer 151 are provided, instead of the first hole transport assistance layer 142 and the first green emission layer 152a of the first and second subpixels GS1 and GS2, and common layers 131, 132, 133, 134, 135, 136, and 160 are provided in the same manner as in the first and second subpixels GS1 and GS2. In the fourth subpixel RS, the light emitting element has a stacking sequence of anode 110, a hole injection layer 131, a hole transport layer 132, a second hole transport assistance layer 141, an electron blocking layer 133, a red emission layer 153, a hole blocking layer 134, an electron transport layer 135, an electron injection layer 136, and a cathode 160.

A host material used for the red emission layer 151 may have an aryl group as a core, and may be selected from the group consisting of the aryl group, a substituted or non-substituted aryl group having a carbon number of 6 to 24, a substituted or non-substituted heteroaryl group, a substituted or non-substituted condensed aryl group having a carbon number of 10 to 30, a substituted or non-substituted heteroaryl group having a carbon number of 2 to 24, a substituted or non-substituted alkyl group having a carbon number of 1 to 24, a substituted or non-substituted heteroalkyl group having a carbon number of 1 to 24, a substituted or non-substituted cycloalkyl group having a carbon number of 3 to 24, a substituted or non-substituted alkoxy group having a carbon number of 1 to 24, a substituted or non-substituted aryloxy group having a carbon number of 6 to 24, a substituted or non-substituted alkylsilyl group having a carbon number of 1 to 24, a substituted or non-substituted arylsilyl group having a carbon number of 6 to 24, a cyano group, a halogen group, deuterium, and hydrogen. R˜R14 may form a condensed ring together with a neighboring substituent.

The component constituting the core, which is an aryl group, may be selected from the group consisting of phenyl, naphthalene, fluorine, carbazole, phenazine, phenanthroline, phenanthridine, acridine, cinnoline, quinazoline, quinoxaline, naphthyridine, phthalazine, quinolizine, indole, indazole, pyridazine, pyrazine, pyrimidine, pyridine, pyrazole, imidazole, and pyrrole.

As an example, the host of the red emission layer 151 may be made of CBP, CDBP, mCP, BCP, BAlq, or TAZ, and one or more materials may be included.

In addition, a dopant is included in the red emission layer 151 in order to emit red light, and Ir(piz)3(Tris(1-phenylisoquinoline)iridium(III), Ir(piq)2(acac)(Bis(1-phenylisoquinoline)(acetylacetonate)iridium(III), Ir(bip)2(acac)(Bis)2-benzolbithiophen-2-yl-pyridime)(acetylacetonate)iridium(III)), or Ir(BT)2(acac)(Bis(2-pheylbenzothazolato)(accetylacetonate)iridium(III) may be used as a phosphorous dopant. However, the present disclosure is not limited thereto.

In addition, fluorescent dopant included in the red emission layer 151 may be Rubrene (5,6,11,12-tetraphenylnaphthacene) and DCJTB (4-(dicyanlmethylene)-2-tert-butyl-6-(1,1,7,7,-tetramethyljuloidin-4-yl-viyl)-4H).

Meanwhile, in the light emitting display device according to the present disclosure, the luminescence peak of the blue emission layer 153 has a wavelength of 420 nm to 500 nm, the luminescence peak of the green emission layer 152 has a wavelength of 500 nm to 590 nm, and the luminescence peak of the red emission layer 151 has a wavelength of 590 nm to 660 nm.

Meanwhile, each of the emission portions GE1, GE2, BE, and RE may be defined in an open area of the bank 180, and the green emission layer 152, the blue emission layer 153, and the red emission layer 151 may be provided in at least the emission portions of the respective subpixels.

The luminescence peak of each emission layer is included in the wavelength transmitted by the color filter located thereon. That is, the luminescence peak of the green emission layer 152 is included in the wavelength transmitted by each of the first and second color filters 321a and 321b, and therefore light emitted from the green emission layer 152 may be transmitted through each of the first and second color filters 321a and 321b without large loss. In the same manner, light emitted from the blue emission layer 153 may be transmitted through the third color filter 322, and light emitted from the red emission layer 151 may be transmitted through the fourth color filter 323.

The emission layers 151, 153, and 152 may overlap at least the emission portions GE, BE, and RE, and may be formed so as to overlap a part of the upper surface of the bank 180 around the emission portions GE, BE, and RE in consideration of margin at the time of deposition.

The first to fourth color filters 321, 321b, 322, and 323 may touch each other between adjacent subpixels, and may be formed so as to correspond to the sizes of the emission layers 151, 153, and 152, as shown in FIG. 2. Each of the emission layers 151, 153, and 152 may be further provided with a black matrix 310. Depending on circumstances, the black matrix 310 may be omitted. When the black matrix 310 is further provided, the black matrix 310 may also perform a function of preventing mixture of colors between adjacent subpixels.

Meanwhile, a capping layer 170 common to the subpixels is formed on the cathode 160. The capping layer 170 may be provided in order to improve the extraction effect of light emitted from the light emitting element and to protect the light emitting element.

For example, the capping layer 170 may be a stack of an organic capping layer and an inorganic capping layer. This is an example. A signal organic capping layer, a single inorganic capping layer, or an organic and inorganic composite capping layer may be provided. For the organic capping layer, the material for one layer of the organic stack may be included. For the inorganic capping layer or when an inorganic material is included, the material may include a fluoride, such as LiF, YbF, or MgF, or a transition metal, such as Yb, in order to improve transmittance of light from the cathode 160.

An encapsulation layer structure 200 constituted by a stack of inorganic encapsulation films 210 and 230 and an organic encapsulation film 220 in order to protect the light emitting element in the substrate 100 and to prevent permeation of external moisture may be provided on the capping layer 170. Depending on circumstances, a passivation film may be provided on the capping layer 170 and the encapsulation substrate may be laminated on the thin film transistor array substrate 1000 through a face seal, instead of the encapsulation layer structure 200.

The first to fourth color filters 321a, 321b, 322, and 323, each of which has an external light blocking function and has a function of transmitting light emitted from a corresponding subpixel, may be further provided on the encapsulation substrate or the encapsulation layer structure 200.

The construction of the thin film transistor TFT connected to the anode 110 will be described.

A combination of the substrate 100 and the thin film transistor array formed on the substrate 100 will be referred to as a thin film transistor array substrate 1000.

Each of the subpixels GS1, BS, GS2, and RS may include at least one thin film transistor TFT, and the thin film transistor TFT may include a gate electrode 102, an active layer 104 overlapping the gate electrode 102, and a drain electrode 106a and a source electrode 106b connected to opposite sides of the active layer 104.

On a channel of the active layer 104, a channel passivation layer 105 configured to protect the channel may be further provided. A gate insulating film 103 may be further provided between the gate electrode 102 and the active layer 104.

The active layer 104 may include at least one of an oxide semiconductor layer, a polysilicon layer, and an amorphous silicon layer.

In addition, the thin film transistor array substrate 1000 may include a first passivation film 107 and a second passivation film 108 configured to protect the thin film transistor TFT. One of the first and second passivation films 107 and 108 may be an inorganic passivation film, and the other may be an organic passivation film.

The anode 110 of the light emitting element may be connected via a contact hoe CT formed through the first and second passivation films 107 and 108 such that a part of the source electrode 106b is exposed.

The emission portion of each subpixel may be defined by the opening of the bank 180.

Meanwhile, although the organic stack structure described above is configured such that each subpixel has a single emission layer, the present disclosure is not limited thereto, and the organic stack may include a plurality of stacks. When the organic stack includes a plurality of stacks, a charge generation layer configured to supply holes and electrons to adjacent stacks may be further provided between the stacks, and each stack may be provided with an emission layer configured to emit color light transmitted through the color filter located thereon, and a common layer related to hole transport and a common layer related to electron transport may be further provided under and above the emission layer. That is, in the multi-stack structure, each stack may include an emission layer configured to emit the same color of light.

### MODE FOR INVENTION

Hereinafter, preferred embodiments of the present disclosure will be described with reference to the accompanying drawings. Throughout the specification, the same or similar elements are denoted by the same reference numerals. In the following description, a detailed description of known functions and configurations incorporated herein will be omitted when it may make the subject matter of the disclosure rather unclear. In addition, names of components used in the following description are selected in consideration of ease in preparing the specification, and may be different from names of parts of an actual product.

In the drawings for explaining the exemplary embodiments of the present disclosure, for example, the illustrated shape, size, ratio, angle, and number are given by way of example, and thus, are not limitative of the disclosure of the present disclosure. Throughout the present specification, the same reference numerals designate the same constituent elements. The terms “comprises”, “includes”, and/or “has”, used in this specification, do not preclude the presence or addition of other elements unless used along with the term “only.” The singular forms are intended to include the plural forms as well, unless the context clearly indicates otherwise.

In the interpretation of constituent elements included in the various embodiments of the present disclosure, the constituent elements are interpreted as including an error range even if there is no explicit description thereof.

When describing positional relationships, for example, when the positional relationship between two parts is described using “on”, “above”, “below”, “beside”, or the like, one or more other parts may be located between the two parts unless the term “directly” or “closely” is used therewith.

When the temporal relationship between two actions is described using “after”, “subsequently”, “next”, “before”, or the like, the actions may not occur in succession unless the term “immediately” or “directly” is used therewith.

In the description of the various embodiments of the present disclosure, although terms such as, for example, “first” and “second” may be used to describe various elements, these terms are merely used to distinguish the same or similar elements from each other. Therefore, in the present specification, an element modified by “first” may be the same as an element modified by “second” within the technical scope of the present disclosure unless mentioned otherwise.

The respective features of the various embodiments of the present disclosure may be partially or wholly coupled to and combined with each other, and various technical linkages therebetween and operation methods thereof are possible. These various embodiments may be performed independently of each other, or may be performed in association with each other.

In this specification, the term “doped” means that a material of any layer, which has physical properties (e.g., N-type and P-type, or an organic material and an inorganic material) different from the material that occupies the greatest weight percentage of the corresponding layer, is added to the material accounting for the greatest weight percentage in an amount corresponding to a weight percentage of less than 30%. In other words, a “doped” layer means a layer in which a host material and a dopant material of any layer are distinguishable from each other in consideration of the weight percentages thereof. In addition, the term “undoped” refers to all cases excluding the case that corresponds to the term “doped”. For example, when any layer is formed of a single material or is formed of a mixture of materials having the same or similar properties, the layer is an “undoped” layer. For example, when at least one of constituent materials of any layer is of a P-type and not all of the other constituent materials of the layer are of an N-type, the layer is an “undoped” layer. For example, when at least one of the constituent materials of any layer is an organic material and not all of the other constituent materials of the layer are an inorganic material, the layer is an “undoped” layer. For example, when all constituent materials of any layer are organic materials, at least one of the constituent materials is of an N-type, at least another constituent material is of a P-type, and the weight percent of the N-type material is less than 30% or the weight percent of the P-type material is less than 30%, the layer is a “doped” layer.

Meanwhile, in this specification, an electroluminescence (EL) spectrum is calculated via the product of (1) a photoluminescence (PL) spectrum that represents unique properties of an emissive material such as a dopant or host material included in an organic emissive layer and (2) an outcoupling emittance spectrum curve determined depending on the structure and optical properties of an organic light-emitting device including thicknesses of organic layers such as an electron transport layer.

FIG. 1 is a plan view showing a light emitting display device according to a first embodiment of the present disclosure, and FIG. 2 is a sectional view showing a light emitting element provided in each of first and second subpixels of FIG. 1. FIG. 3 is a sectional view taken along line I-I′ of FIG. 1. In addition, FIG. 4 is a graph showing transmission characteristics of a first color filter and a second color filter of the light emitting display device according to the present disclosure and effects in transmission characteristics of the first and second color filters due to 1:1 disposition thereof.

As shown in FIGS. 1 and 2, the light emitting display device according to the first embodiment of the present disclosure includes first subpixels GS1 and second subpixels GS2 provided on a substrate 100 so as to be spaced apart from each other, each of the first subpixels and the second subpixels being configured to emit a first color of light, third subpixels BS and fourth subpixels RS spaced apart from the first and second subpixels GS1 and GS2, each of the third subpixels being configured to emit a second color of light, which is different from the first color of light, each of the fourth subpixels being configured to emit a third color of light, which is different from the first color of light, a first color filter 321a provided at each of the first subpixels GS1, the first color filter being configured to transmit the first color of light emitted from the first subpixel GS1 while having a first peak, a second color filter 321b provided at each of the second subpixels GS2, the first color filter being configured to transmit the first color of light emitted from the second subpixel GS2 while having a second peak, which has a longer wavelength than the first peak, and third and fourth color filters 322 and 323 provided respectively at the third and fourth subpixels BS and RS, the third and fourth color filters being configured to respectively transmit the third color of light and the fourth color of light.

In the light emitting display device according to the present disclosure, as shown in FIG. 4, the first subpixel GS1 and the second subpixels GS2, which emit the same color of light, have different transmittances, wherein a first color filter G_CF1 (321a of FIG. 3) and a second color filter G_CF2 (321b of FIG. 3) are provided, whereby peaks of light finally transmitted through the first and second subpixels GS1 and GS2 are different from each other. Here, a second peak P2 of the second color filter 321b has a longer wavelength than a first peak P1 of the first color filter 321a. When the first and second color filters 321a and 321b, which are different from each other, are applied, there is an effect in that full width at half maximum of light emitted from both the first and second subpixels GS1 and GS2 is greater than full width at half maximum of each of the first and second color filters 321a and 321b, as expressed by Average in FIG. 4, compared to when a single color filter is applied. In addition, an increase in full width at half maximum may compensate for luminance, whereby it is possible to prevent or alleviate a decrease in luminance due to a change in viewing angle.

A polarizer reduces transmittance of light emitted from a light emitting element in all wavelengths by half. In a structure in which the polarizer is used, therefore, power consumption must be increased in consideration of transmittance of light reduced by half by the polarizer. In contrast, in the light emitting display device according to the present disclosure, each of the first to fourth color filters 321a, 321b, 322, and 323 is transmissive to a specific wavelength.

Consequently, transmittance of color light emitted from the light emitting element subpixel may be increased, whereby gamut may be increased, and current necessary to turn on the light emitting element may be reduced, compared to the structure in which the polarizer is provided, whereby power consumption may be reduced.

It is advantageous that the peak difference (P2−P1) between the first and second color filters 321a and 321b is greater, since full width at half maximum is further increased; however, the first and second subpixels GS1 and GS2 in which the first and second color filters 321a and 321b are disposed must emit the same color of light without sense of difference. For this reason, the peak difference (P2−P1) of light transmitted through the first and second color filters 321a and 321b may be 20 nm or less. In addition, it was confirmed through the following experiments that, when the peak difference between the first and second color filters 321a and 321b was about 4 nm or more, a decrease in luminance due to a change in viewing angle was meaningfully alleviated. That is, when the difference between the first and second peaks of the first and second color filters 321a and 321b according to the present disclosure is 4 nm to 20 nm, it is possible to maintain emission characteristics of the same color of light and to reduce a decrease in luminance due to a change in viewing angle.

At time, the first peak P1, which has a relatively short wavelength, may have a wavelength of 510 nm to 550 nm, and the second peak P2 may have a wavelength of 514 nm to 570 nm. In any case, the second peak P2 has a longer wavelength than the first peak P1.

As shown in FIG. 1, the first and second color filters 321a and 321b may be parallel to each other, and may be disposed so as not to overlap emission portions BE and RE of the third and fourth subpixels BS and RS. In this case, when the first and second color filters 321a and 321b are disposed long in a vertical direction, as shown in FIG. 1, each of the first and second color filters 321a and 321b may have a relatively large width in an area in which the first and second emission portions GE1 and GE2, which are long in a diagonal direction, and may have a small width so as not to neighbor the blue emission portion BE and the red emission portion RE in an area in which the first and second emission portions GEL and GE2 are located in a horizontal direction. In addition, the first and second color filters 321a and 321b may be vertically parallel to each other, as shown in FIG. 1, or may be horizontally parallel to each other, depending on circumstances. Depending on circumstances, the first and second color filters may be parallel to each other in the diagonal direction depending on diagonal disposition of the first and second emission portions GEL and GE2.

In the light emitting display device according to the present disclosure, the subpixel having the first and second color filters 321a and 321b having different transmittances applied thereto is a green subpixel as an example. The reason for this is that green emission greatly contributes to expression of white light, and therefore the number of green subpixels is increased. When the light emitting display device has a structure in which the number of other color subpixels is increased, the color subpixels disposed so as to be disposed at a relatively higher percentage may be divided into two groups, to which different color filters configured to have transmittances having a peak difference within a predetermined wavelength may be applied, whereby it is possible to improve luminance depending on a change in viewing angle for the color.

An example in which the green emission portions are denoted by GE1 and GE2, the blue emission portion is denoted by BE, and the red emission portion is denoted by RE in arrangement of the subpixels shown in FIG. 1 will be briefly described.

The first subpixel GS1 includes the first green emission portion GEL and a part of a bank 180 therearound, and the second subpixel GS2 includes the second green emission portion GE2 and a part of the bank 180 therearound. In addition, the third subpixel BS includes the blue emission portion BE and a part of the bank 180 therearound, and the fourth subpixel RS includes the red emission portion RE and a part of the bank 180 therearound.

It is preferable for the first and second green emission portion GE1 and GE2 to have the same size and the same shape in order) achieve a symmetrical and supplementary effect.

The blue emission portion BE and the red emission portion RE may have the same shape as the first and second green emission portions GE1 and GE2; however, the shape and size thereof may be adjusted in consideration of the efficiency, lifespan characteristics, and transmittance of each emission portion.

In the example shown, each of the first and second green emission portions GEL and GE2 is disposed long in the diagonal direction, wherein opposite ends thereof are rounded, the blue emission portion BE is formed in an appropriate diamond shape, wherein each vertex of the diamond shape is rounded, and the red emission portion RE is circular. However, this is an example, and change to other shapes is possible.

As shown in FIG. 1, the first and second subpixels GS1 and GS2 respectively having the first and second green emission portions GE1 and GE2 may be alternately disposed in a row or a column.

In this case, the first subpixels GS1 and the second subpixels GS2 may be disposed side by side, and the third subpixels BS and the fourth subpixels RS are disposed in parallel to the first subpixels GS1 while being alternately disposed between the first and second subpixels GS1 and GS2 that are disposed side by side while being adjacent to each other.

The first to fourth subpixels GS1, GS2, BS, and RS may be repeatedly disposed in an imaginary diamond shape.

Meanwhile, the emission portions GE1, GE2, BE, and RE of the first to fourth subpixels GS1, GS2, BS, and RS are surrounded by the bank 180, whereby the areas thereof are defined.

The sectional construction of the light emitting display device according to the present disclosure will be described in detail with reference to FIGS. 2 and 3.

In FIG. 3, a light emitting element OLED located at each of the emission portions GEL, GE2, BE, and RE may include an anode 110, a cathode 160, and an organic stack located between the anode 110 and the cathode 160.

Each emission portion GE1, GE2, BE, or RE may include at least one emission layer 152, 152, 153, or 151, as the minimum construction, a common layer under the emission layer, and a common layer above the emission layer. In addition to the common layers, an optical compensation layer configured to selectively adjust optical distance from a specific emission portion or an adjustment layer having a hole blocking function or an electron blocking function may be further included.

FIG. 2 shows the construction of an organic stack according to an example.

The construction of the first subpixel GS1 and the second subpixel GS2 will be described with reference to FIG. 2.

An organic stack including a hole injection layer 131, a hole transport layer 132, a first hole transport assistance layer 142, an electron blocking layer 133, a green emission layer 152, and an electron transport layer 135 sequentially arranged may be provided on a first anode 110. In addition, an electron injection layer 136 is provided on the electron transport layer 135, and a cathode 160 is provided on the electron injection layer 136.

The electron injection layer 136, which directly abuts the cathode 160, may include an inorganic dopant or may be made of only an inorganic material. Consequently, the electron injection layer may be a component of the cathode 160. The electron injection layer 136 may be formed together with the cathode 160 in the previous step of the cathode 160. That is, the electron injection layer 136 and the cathode 160 may be continuously formed in the same chamber in the state in which only materials that are supplied are different from each other.

In the organic stack, the hole injection layer 131, the electron blocking layer 133, a hole blocking layer 134, and the electron transport layer 135 are common layers formed irrespective of subpixels excluding that the first hole transport assistance layer 142, which is provided to adjust optical distance from the green emission portion, is optionally formed in the first and second subpixels GS1 and GS2. In addition, the electron injection layer 136 and the cathode 160 formed on the electron transport layer 135 are common layers formed irrespective of subpixels. The common layer may be formed without a mask having microscopic openings, such as a fine metal mask (FMM), and is a layer formed integrally so as to cover all subpixels provided in a display area of the substrate 100.

Meanwhile, FIG. 2 shows that the light emitting element has a single organic stack; however, the present disclosure is not limited thereto, and the light emitting element may have a plurality of stacks.

The green emission layer 152 of each of the first and second subpixels GS1 and GS2 may include a green host gh and a green dopant gd. The green host gh may include a plurality of different hosts. Examples of the green host gh may include C-545T (10-(2-benzothia-zylyl)-1,1,7,7-tetramethyl-2,3,6,7-tetrahydro-1H, 5H, 11H-[1]benzo-pyrano [6,7,8-ij]quinolizin-11-one) using Alq3 as a matrix, derivatives thereof, quinacridone derivatives, and carbazole derivatives. When Alq3 is used as the host, green emission is possible; however, another green dopant may be included in order to improve green emission efficiency.

The third subpixel BS has no hole transport assistance layer, unlike the first and second subpixels GS1 and GS2 and the fourth subpixel RS. Hole transport assistance layers 141 and 142 are provided to adjust different optical distances from different color emission layers. Since an emission area is formed a relatively short distance from the anode 110, the third subpixel BS, which emits blue light, has no hole transport assistance layer.

In the blue subpixel BS, the light emitting element has a stacking sequence of an anode 110, a hole injection layer 131, a hole transport layer 132, an electron blocking layer 133, a blue emission layer 153, a hole blocking layer 134, an electron transport layer 135, an electron injection layer 136, and a cathode 160.

The blue emission layer 153 may include at least one blue host and at least one blue dopant. Specifically, the blue emission layer may be formed by doping at least one fluorescent host material selected from the group consisting of anthracene an derivative, a pyrene derivative, and a perylene derivative with a pyrene-based or boron-based fluorescent blue dopant. When a phosphorescent blue material stable as a blue dopant is developed, replacement may be possible.

Each of the first and second subpixels GS1 and GS2, in which the distance between the optimum emission area in the emission layer and the anode 110 is large, compared to the blue subpixel BS, has a first hole transport assistance layer 142, and the red subpixel RS has a second hole transport assistance layer 141. Since optical distances of red and green colors are different from each other, there may be a difference in thickness between the first hole transport assistance layer 142 and the second hole transport assistance layer 141. In addition, it is possible to adjust optical distance of each emission layer through the thickness difference between the emission layers 152, 153, and 151. Depending on circumstanced, different hole transport assistance layers and emission layers having different thicknesses may be applied to respective color pixels.

The fourth subpixel RS is different from the first and second subpixels GS1 and GS2 in that a second hole transport assistance layer 141 and a red emission layer 151 are provided, instead of the first hole transport assistance layer 142 and the first green emission layer 152a of the first and second subpixels GS1 and GS2, and common layers 131, 132, 133, 134, 135, 136, and 160 are provided in the same manner as in the first and second subpixels GS1 and GS2. In the fourth subpixel RS, the light emitting element has a stacking sequence of an anode 110, a hole injection layer 131, a hole transport layer 132, a second hole transport assistance layer 141, an electron blocking layer 133, a red emission layer 153, a hole blocking layer 134, an electron transport layer 135, an electron injection layer 136, and a cathode 160.

A host material used for the red emission layer 151 may have an aryl group as a core, and may be selected from the group consisting of the aryl group, a substituted or non-substituted aryl group having a carbon number of 6 to 24, a substituted or non-substituted heteroaryl a group, substituted or non-substituted condensed aryl group having a carbon number of 10 to 30, a substituted or non-substituted heteroaryl group having a carbon number of 2 to 24, a substituted or non-substituted alkyl group having a carbon number of 1 to 24, a substituted or non-substituted heteroalkyl group having a carbon number of 1 to 24, a substituted or non-substituted cycloalkyl group having a carbon number of 3 to 24, a substituted or non-substituted alkoxy group having a carbon number of 1 to 24, a substituted or non-substituted aryloxy group having a carbon number of 6 to 24, a substituted or non-substituted alkylsilyl group having a carbon number of 1 to 24, a substituted or non-substituted arylsilyl group having a carbon number of 6 to 24, a cyano group, a halogen group, deuterium, and hydrogen. R˜R14 may form a condensed ring together with a neighboring substituent.

The component constituting the core, which is an aryl group, may be selected from the group consisting of phenyl, naphthalene, fluorine, carbazole, phenazine, phenanthroline, phenanthridine, acridine, cinnoline, quinazoline, quinoxaline, naphthyridine, phthalazine, quinolizine, indole, indazole, pyridazine, pyrazine, pyrimidine, pyridine, pyrazole, imidazole, and pyrrole.

As an example, the host of the red emission layer 151 may be made of CBP, CDBP, mCP, BCP, BAlq, or TAZ, and one or more materials may be included.

In addition, a dopant is included in the red emission layer 151 in order to emit red light, and Ir(piz)3(Tris(1-phenylisoquinoline)iridium(III), Ir(piq)2(acac)(Bis(1-phenylisoquinoline)(acetylacetonate)iridium(III), Ir(bip)2(acac)(Bis)2-benzolbithiophen-2-yl-pyridime)(acetylacetonate)iridium(III)), or Ir(BT)2(acac)(Bis(2-pheylbenzothazolato)(accetylacetonate)iridium(III) may be used as a phosphorous dopant. However, the present disclosure is not limited thereto.

In addition, examples of a fluorescent dopant included in the red emission layer 151 may be Rubrene (5,6,11,12-tetraphenylnaphthacene) and DCJTB (4-(dicyanlmethylene)-2-tert-butyl-6-(1,1,7,7,-tetramethyljuloidin-4-yl-viyl)-4H).

Meanwhile, in the light emitting display device according to the present disclosure, the luminescence peak of the blue emission layer 153 has a wavelength of 420 nm to 500 nm, the luminescence peak of the green emission layer 152 has a wavelength of 500 nm to 590 nm, and the luminescence peak of the red emission layer 151 has a wavelength of 590 nm to 660 nm.

Meanwhile, each of the emission portions GE1, GE2, BE, and RE may be defined in an open area of the bank 180, and the green emission layer 152, the blue emission layer 153, and the red emission layer 151 may be provided in at least the emission portions of the respective subpixels.

The luminescence peak of each emission layer is included in the wavelength transmitted by the color filter located thereon. That is, the luminescence peak of the green emission layer 152 is included in the wavelength transmitted by each of the first and second color filters 321a and 321b, and therefore light emitted from the green emission layer 152 may be transmitted through each of the first and second color filters 321a and 321b without large loss. In the same manner, light emitted from the blue emission layer 153 may be transmitted through the third color filter 322, and light emitted from the red emission layer 151 may be transmitted through the fourth color filter 323.

The emission layers 151, 153, and 152 may overlap at least the emission portions GE, BE, and RE, and may be formed so as to overlap a part of the upper surface of the bank 180 around the emission portions GE, BE, and RE in consideration of margin at the time of deposition.

The first to fourth color filters 321, 321b, 322, and 323 may touch each other between adjacent subpixels, and may be formed so as to correspond to the sizes of the emission layers 151, 153, and 152, as shown in FIG. 2. Each of the emission layers 151, 153, and 152 may be further provided with a black matrix 310. Depending on circumstances, the black matrix 310 may be omitted. When the black matrix 310 is further provided, the black matrix 310 may also perform a function of preventing mixture of colors between adjacent subpixels.

Meanwhile, a capping layer 170 common to the subpixels is formed on the cathode 160. The capping layer 170 may be provided in order to improve the extraction effect of light emitted from the light emitting element and to protect the light emitting element.

For example, the capping layer 170 may be a stack of an organic capping layer and an inorganic capping layer. This is an example. A signal organic capping layer, a single inorganic capping layer, or an organic and inorganic composite capping layer may be provided. For the organic capping layer, the material for one layer of the organic stack may be included. For the inorganic capping layer or when an inorganic material is included, the material may include a fluoride, such as LiF, YbF, or MgF, or a transition metal, such as Yb, in order to improve transmittance of light from the cathode 160.

An encapsulation layer structure 200 constituted by a stack of inorganic encapsulation films 210 and 230 and an organic encapsulation film 220 in order to protect the light emitting element in the substrate 100 and to prevent permeation of external moisture may be provided on the capping layer 170. Depending on circumstances, a passivation film may be provided on the capping layer 170 and the encapsulation substrate may be laminated on the thin film transistor array substrate 1000 through a face seal, instead of the encapsulation layer structure 200.

The first to fourth color filters 321a, 321b, 322, and 323, each of which has an external light blocking function and has a function of transmitting light emitted from a corresponding subpixel, may be further provided on the encapsulation substrate or the encapsulation layer structure 200.

The construction of the thin film transistor TFT connected to the anode 110 will be described.

A combination of the substrate 100 and the thin film transistor array formed on the substrate 100 will be referred to as a thin film transistor array substrate 1000.

Each of the subpixels GS1, BS, GS2, and RS may include at least one thin film transistor TFT, and the thin film transistor TFT may include a gate electrode 102, an active layer 104 overlapping the gate electrode 102, and a drain electrode 106a and a source electrode 106b connected to opposite sides of the active layer 104.

On a channel of the active layer 104, a channel passivation layer 105 configured to protect the channel may be further provided. A gate insulating film 103 may be further provided between the gate electrode 102 and the active layer 104.

The active layer 104 may include at least one of an oxide semiconductor layer, a polysilicon layer, and an amorphous silicon layer.

In addition, the thin film transistor array substrate 1000 may include a first passivation film 107 and a second passivation film 108 configured to protect the thin film transistor TFT. One of the first and second passivation films 107 and 108 may be an inorganic passivation film, and the other may be an organic passivation film.

The anode 110 of the light emitting element may be connected via a contact hoe CT formed through the first and second passivation films 107 and 108 such that a part of the source electrode 106b is exposed.

The emission portion of each subpixel may be defined by the opening of the bank 180.

Meanwhile, although the organic stack structure described above is configured such that each subpixel has a single emission layer, the present disclosure is not limited thereto, and the organic stack may include a plurality of stacks. When the organic stack includes a plurality of stacks, a charge generation layer configured to supply holes and electrons to adjacent stacks may be further provided between the stacks, and each stack may be provided with an emission layer configured to emit color light transmitted through the color filter located thereon, and a common layer related to hole transport and a common layer related to electron transport may be further provided under and above the emission layer. That is, in the multi-stack structure, each stack may include an emission layer configured to emit the same color of light.

Hereinafter, another embodiment will be described.

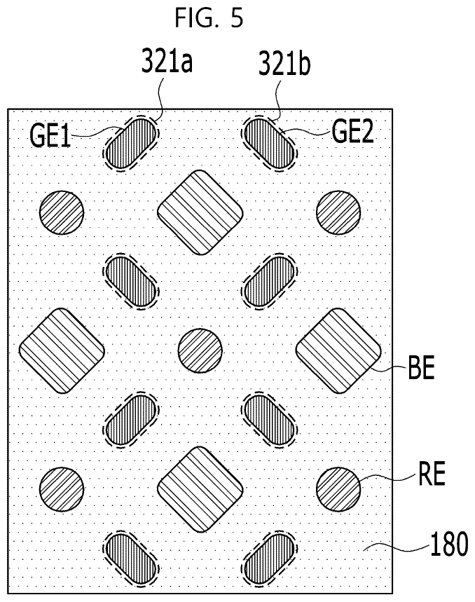

FIG. 5 is a plan view showing a light emitting display device according to a second embodiment of the present disclosure.

As shown in FIG. 5, the light emitting display device according to the second embodiment of the present disclosure is configured such that first and second color filters 321a and 321b are provided so as to correspond to first and second green emission portions GEL and GE2. In this case, the first and second color filters 321a and 321b may be disposed in an island shape, not a line shape.

The first and second color filters 321a and 321b shown in FIG. 5 are formed so as to have sizes corresponding to the first and second green emission portions GE1 and GE2; however, the present disclosure is not limited thereto. The first and second color filters 321a and 321b may also extend to the outside of the emission portions so as to further overlap non-emission portions unless the first and second color filters do not abut other color emission portions adjacent thereto.

In addition, although not shown in FIG. 5, third color filters (322 of FIG. 3) may be provided in an island shape so as to correspond to blue emission portions BE, and fourth color filters (323 of FIG. 3) may be provided in an island shape so as to correspond to red emission portions RE, in the same manner. The third color filters 322 and 323 may be formed so as to have sizes equal to or greater than the sizes of the blue emission portions BE and red emission portions RE unless the third color filters overlap other color emission portions.

Meanwhile, in the light emitting display device according to the present disclosure, the first to fourth color filters 321a, 321b, 322, and 323 may be provided on the encapsulation layer structure 200 or the encapsulation substrate in order to absorb external light using selective wavelength transmittance of each color filter.

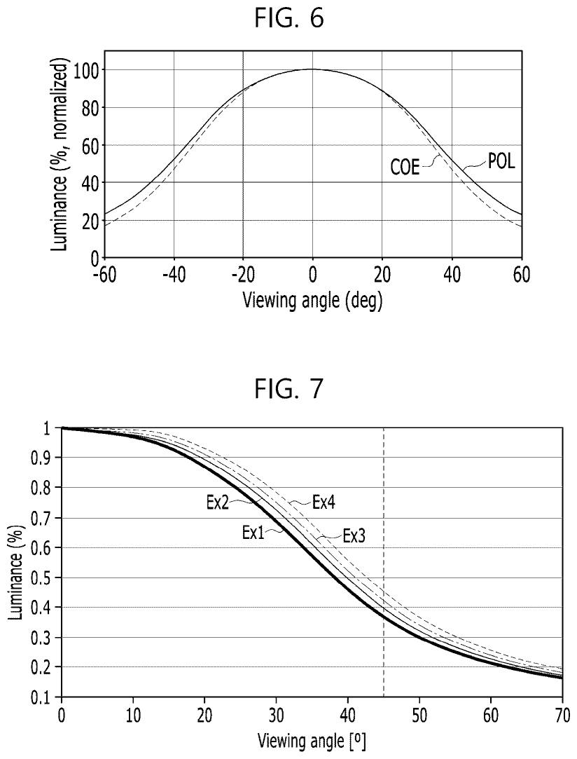

FIG. 6 is a graph showing white luminance based on a viewing angle when a polarizer is applied to an upper side of an emission portion and when a color filter is applied to the upper side of the emission portion.

When a single color filter is applied to the upper side of the emission portion for each subpixel (COE), as shown in FIG. 6, it is possible to increase color gamut and to reduce power consumption, compared to when the polarizer is applied to the upper side of the emission portion (POL). Since a black matrix or a color filter is provided in a non-emission portion, however, luminance is more greatly reduced as the viewing angle is increased than when the polarizer is applied (POL). At a viewing angle of about 45°, the luminance in the structure in which h the polarizer is applied is 42% of front luminance, whereas the luminance when the color filter is applied is 37% of front luminance, and therefore a relative decrease in luminance is observed.

In the present disclosure, first and second color filters having different peak transmittances are applied to the first and second subpixels in order to prevent a decrease in luminance when the viewing angle is changed.

FIG. 7 is a graph showing a change in luminance depending on the viewing angle in first to fourth experimental examples.

TABLE 1

| | Luminance efficiency (%) based on peak difference | | | |
|---|---|---|---|---|
| Viewing | (P2 − P1) | | | |
| angle (°) | Ex1 (0 nm) | Ex2 (4 nm) | Ex3 (8 nm) | Ex4 (12 nm) |
| 0 | 100.0 | 100.0 | 100.0 | 100.0 |
| 5 | 99.1 | 99.4 | 99.6 | 99.8 |
| 10 | 96.9 | 97.7 | 98.3 | 98.9 |
| 15 | 93.3 | 94.8 | 96.0 | 97.3 |
| 20 | 87.0 | 89.3 | 91.1 | 93.1 |
| 25 | 78.8 | 81.8 | 84.1 | 86.8 |
| 30 | 68.7 | 72.3 | 75.1 | 78.3 |
| 35 | 57.1 | 61.0 | 64.0 | 67.5 |
| 40 | 46.0 | 49.4 | 52.3 | 55.7 |
| 45 | 36.8 | 39.7 | 42.1 | 45.2 |
| 50 | 29.9 | 32.1 | 34.0 | 36.6 |
| 55 | 25.0 | 26.7 | 28.2 | 30.2 |
| 60 | 21.3 | 22.6 | 23.8 | 25.5 |
| 65 | 18.5 | 19.6 | 20.6 | 22.0 |
| 70 | 16.3 | 17.3 | 18.1 | 19.3 |

Referring to FIG. 7 and Table 1, first and second color filters 321a and 321b having peak differences of 4 nm, 8 nm, and 12 nm were applied to the first and second subpixels GS1 and GS2 of FIG. 1 in the second to fourth experimental examples (Ex2 to Ex4), and a single color filter was applied in the first experimental example (Ex1).

It can be seen from FIG. 7 and Table 1 that, in the second to fourth experimental examples (Ex2 to Ex4), the luminance decrease efficiency was alleviated even though the viewing angle was increased (the angle inclined from the front was increased), compared to the experimental example (Ex1). Also, it can be seen that, as the peak difference in transmitted light between the first and second color filters 321a and 321b was increased, the effect of reducing the luminance decrease was improved depending on a change in viewing angle. In the above experiment, the peak difference was 12 nm. As the peak difference is increased, however, the sum of full width at half maximum is increased through application of the two color filters described with reference to FIG. 4, whereby a decrease in luminance due to a change in viewing angle may be reduced.

In the present disclosure, however, the peak difference may be 20 nm or less in order to prevent heterogeneity in visible colors in that the first and second subpixels GS1 and GS2 emit the same color of light.

Meanwhile, the effects other than reduction of a decrease in luminance due to a change in viewing angle of the light emitting display device according to the present disclosure will be described.

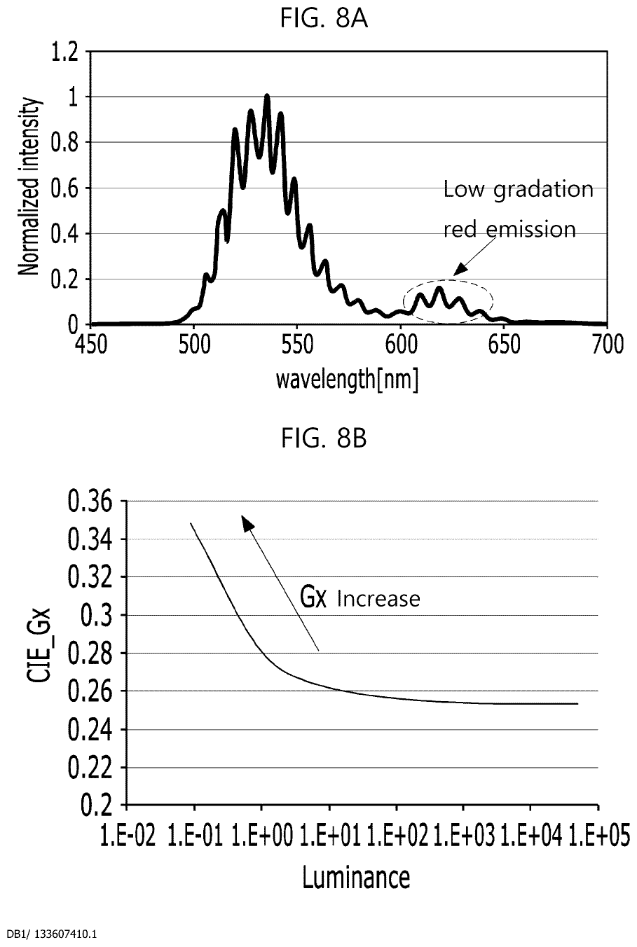

FIG. 8A is a graph showing light intensity depending on wavelength when a green subpixel emits low-gradation light in the first experimental example, and FIG. 8B is a graph showing a change in CIEx of the green subpixel depending on gradation in the first experimental example.

When comparing critical voltages necessary for the respective color emission layers to emit light, the critical voltage of the green emission layer is higher than the critical voltage of the red emission layer. As a result, as shown in FIG. 8A, when only the green emission layer is weakly turned on at low gradation in the first experimental example (Ex1), in which only a single green color filter is applied to each green subpixel, a phenomenon in which red light is unintentionally emitted occurs. In this case, as shown in FIG. 8B, a phenomenon in which the value of CIEx color coordinates of green is increased due to weak red emission occurs. As described above, a phenomenon in which red light unintentionally leaks when low-gradation green light is emitted in the first experimental example (Ex1) is observed. In the light emitting display device according to the present disclosure, different first and second color filters are applied and driving of the light emitting elements of the first and second subpixels is adjusted to solve such current leakage and light leakage problems.

For reference, low gradation means driving at a current density of 10 mA/cm² or less.

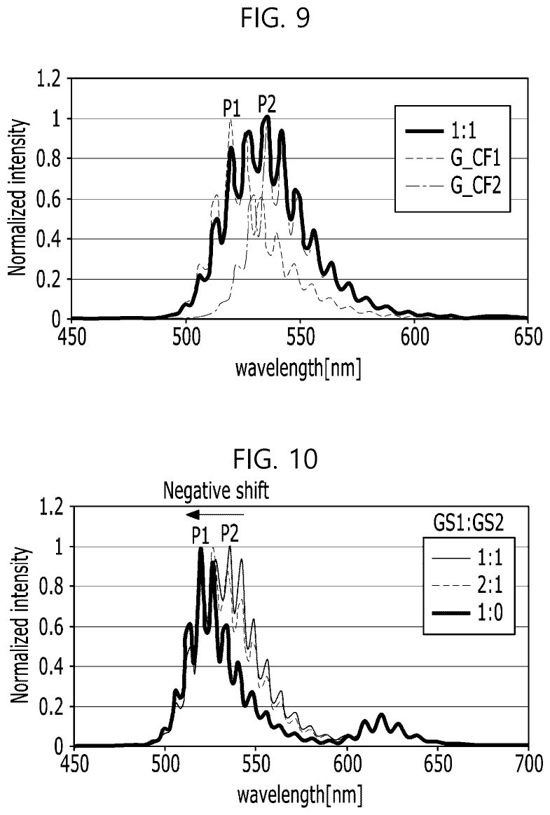

FIG. 9 is a graph showing transmission characteristics of each of first and second color filters according to the present disclosure and transmission characteristics of the first and second color filters when disposed on a substrate at a ratio of 1:1, and FIG. 10 is a graph showing light intensity depending on wavelength when each of first and second subpixels according to the present disclosure emits low-gradation light and when both the first and second subpixels emit low-gradation light.

In the light emitting display device according to the present disclosure, the first and second color filters are disposed at a ratio of 1:1, and a first color filter G_CF1 having a transmission power of a first peak and a second color filter G_CF2 having a transmission power of the first peak and a second peak having a long wavelength longer than that of the first peak by 4 nm to 20 nm correspond to the first and second subpixels GS1 and GS2, respectively.

In this case, when the light emitting elements of the first and second subpixels GS1 and GS2 are turned on, green light having passed through the first and second color filters G_CF1 and G_CF2 is transmitted through an area in which transmission graphs of the first and second color filters G_CF1 and G_CF2 overlap each other of FIG. 9 and left and right transmission graphs of the first and second color filters G_CF1 and G_CF2 at left and right sides of the overlap area.

Meanwhile, in the light emitting display device according to the present disclosure, when driving is performed at a high gradation of more than 10 mA/cm² or intermediate gradation, the emission ratio of the first and second subpixels may be adjusted so as to have characteristics similar to high gradation, as shown in Table 2, whereby it is possible to prevent visibility of red leakage light.

Referring to Table 2 below, in a structure including first and second subpixels GS1 and GS2 provided with first and second color filters having different peaks, as in the light emitting display device according to the present disclosure, the emission level of the first and second subpixels GS1 and GS2 during low-gradation driving (a current density of 10 mA/cm² or less) was changed in fifth to seventh experimental examples (Ex5, Ex6, Ex7, and Ex8) in order to measure a change in color coordinates. FIG. 10 shows the cases in which the emission ratio of the first and second subpixels GS1 and GS2 is 1:1, 2:1, and 1:0.

Here, compared normal high-gradation green coordinates (CIEx, CIEy) are (0.252, 0.712). In addition, the first color filter provided in the first subpixel GS1 is G_CF1 having a short-wavelength transmission power of FIG. 9.

TABLE 2

| | | | | ΔGxv |
|---|---|---|---|---|
| | GS1:GS2 | | | (Compared |
| Division | Emission ratio | Gx (CIEx) | Gy (CIEy) | CIEx = 0.252) |
| Ex5 | 1:1 | 0.281 | 0.685 | 0.029 |
| Ex6 | 2:1 | 0.268 | 0.692 | 0.017 |
| Ex7 | 10:1 | 0.253 | 0.698 | 0.001 |
| Ex8 | 1:0 | 0.248 | 0.700 | −0.004 |

Referring to Table 2 and FIG. 10, it can be seen that, when the first subpixel GS1 corresponding to the first color filter 321a having a relatively short-wavelength transmission power emits a larger amount of light than the second subpixel GS2 corresponding to the second color filter 321b having a relatively long-wavelength transmission power, the value of Gx (CIEx) is similar to the value of Gx (CIEx) of normal high-gradation color coordinates. Referring to Table 2, when the first subpixel GS1 has a percentage of 10 and the second subpixel GS2 has a percentage of 1, the value of Gx (CIEx) is similar to the value of Gx of the normal high-gradation color coordinates. When the percentage of the subpixel corresponding to the color filter having the relatively short-wavelength transmission power is increased, the value of Gx is decreased, whereby a negative shift effect of the wavelength is achieved. At the time of light emission, the intensity of short-wavelength light is increased, whereby visibility of weak leakage light having a long wavelength is prevented, and therefore optical compensation is achieved.

Meanwhile, the degree of preventing visibility of leakage light may be changed depending on the magnitude of leakage current. Commonly, however, a larger number of light emitting elements corresponding to a color filter having higher transmission power with respect to a short wavelength may be turned on.

In addition, relatively increased emission of the light emitting element is possible by turning on the thin film transistor connected to the light emitting element.

In the light emitting display device according to the present disclosure described above, color filters capable of preventing reflection of external light may be further provided above light emitting elements on substrate, whereby it is possible to omit a polarizer, and therefore it is possible to increase color gamut and to reduce power consumption.

Also, in the light emitting display device according to the present disclosure described above, in correspondence between color filters and light emitting elements that emit light having wavelengths transmitted through the color filters, light emitting elements that emit at least one color of light is divided into two parts, and first and second color filters having transmittance for light having different peaks are applied thereto, whereby it is possible to prevent or alleviate a phenomenon in which luminance is reduced depending on a change in viewing angle.

In addition, the light emitting display device according to the present disclosure has a structure in which different color filters having different peak transmittances correspond to first and second light emitting elements alternately disposed so as to emit the same color of light. In this structure, percentage in emission through the color filter having relatively short-wavelength transmittance during low-gradation driving may be increased, whereby negative shift to the short wavelength is achieved, and therefore it is possible to prevent visibility due to other color emission during low-gradation driving.

Meanwhile, in the light emitting display device according to the present disclosure, the first and second subpixels may be disposed at a ratio other than a ratio of 1:1. When the first and second subpixels are disposed at a ratio other than a ratio of 1:1, however, the peak difference between the first and second color filters corresponding to the first and second subpixels required to compensate for the transmission power at the side having a small percentage of disposition for symmetry of the light emitting display device may be changed.

In consideration of the fact that luminance is reduced depending on a change in viewing angle, it is advantageous to dispose the first and second subpixels corresponding to the first and second color filters at a ratio of 1:1 in order to reduce the peak difference between the first and second color filters and to provide visual characteristics similar to high gradation during low-gradation driving.

It will be apparent to those skilled in the art that the present disclosure described above is not limited to the above embodiments and the accompanying drawings and that various substitutions, modifications, and variations can be made without departing from the technical idea of the present disclosure.

[Description of Reference Symbols]

| | |
|---|---|
| 100: Substrate | 110: Anode |
| 151: Red emission layer | 152: Green emission layer |
| 153: Blue emission layer | 160: Cathode |
| 170: Capping layer | 200: Encapsulation layer |
| | structure |
| 210, 230: Inorganic encapsulation films | 220: Organic |
| | encapsulation film |
| 310: Black matrix | 321a: First color filter |
| 321b: Second color filter | 322: Third color filter |
| 323: Fourth color filter | GE1: First green |
| | emission portion |
| GE2: Second green emission portion | BE: Blue emission |
| | portion |
| RE: Red emission portion | |

1. A light emitting display device comprising:
first subpixels and second subpixels provided on a substrate to be spaced apart from each other, each of the first subpixels and the second subpixels being configured to emit a first color of light;
third subpixels and fourth subpixels spaced apart from the first and second subpixels, each of the third subpixels being configured to emit a second color of light different from the first color of light, each of the fourth subpixels being configured to emit a third color of light different from the first color of light;
a first color filter provided at each of the first subpixels, the first color filter being configured to transmit the first color of light emitted from the first subpixel while having a first peak;
a second color filter provided at each of the second subpixels, the second color filter being configured to transmit the first color of light emitted from the second subpixel while having a second peak having a longer wavelength than the first peak; and
third and fourth color filters provided respectively at the third and fourth subpixels, the third and fourth color filters being configured to respectively transmit the second color of light and the third color of light.

2. The light emitting display device according to claim 1, wherein a difference between the first peak and the second peak is 4 nm to 20 nm.

3. The light emitting display device according to claim 1, wherein the first peak has a wavelength of 510 nm to 550 nm.

4. The light emitting display device according to claim 1, wherein the first and second subpixels are alternately disposed in a row, in a column, or in a diagonal direction.

5. The light emitting display device according to claim 1, wherein
the first subpixels and the second subpixels are disposed side by side, and
the third subpixels and the fourth subpixels are disposed in parallel to the first subpixels while being alternately disposed between the first and second subpixels disposed side by side while being adjacent to each other.

6. The light emitting display device according to claim 1, wherein
the first subpixels and the third subpixels are alternately disposed along a first diagonal line, and
the second subpixels and the fourth subpixels are alternately disposed along a second diagonal line intersecting the first diagonal line.

7. The light emitting display device according to claim 1, further comprising a black matrix provided between emission portions of the first to fourth subpixels.

8. The light emitting display device according to claim 1, wherein
each of the first to fourth subpixels has an anode and a cathode opposite each other,
each of the first and second subpixels comprises at least one first emission layer provided between the anode and the cathode, the first emission layer being configured to emit the first color of light,
each of the third subpixels comprises at least one second emission layer provided between the anode and the cathode, the second emission layer being configured to emit the second color of light, and
each of the fourth subpixels comprises at least one third emission layer provided between the anode and the cathode, the third emission layer being configured to emit the third color of light.

9. The light emitting display device according to claim 8, wherein the first to fourth subpixels are located at equal vertical intervals from an upper surface of the cathode.

10. The light emitting display device according to claim 9, wherein a capping layer and an encapsulation layer are sequentially provided between the cathode and the first to fourth subpixels.

11. A light emitting display device comprising:
first light emitting elements and second light emitting elements provided on a substrate to be spaced apart from each other, each of the first light emitting elements and the second light emitting elements being configured to emit a first color of light;
third light emitting elements and fourth light emitting elements spaced apart from the first and second light emitting elements, each of the third light emitting elements being configured to emit a second color of light different from the first color of light, each of the fourth light emitting elements being configured to emit a third color of light different from the first color of light;
first to fourth transistors connected respectively to the first to fourth light emitting elements;
a first color filter provided on the first light emitting elements, the first color filter being configured to transmit the first color of light while having a first peak;
a second color filter provided on the second light emitting elements, the second color filter being configured to transmit the first color of light while having a second peak having a longer wavelength than the first peak; and
third and fourth color filters provided on the third and fourth light emitting elements, the third and fourth color filters being configured to respectively transmit the second color of light and the third color of light.

12. The light emitting display device according to claim 11, wherein a difference between the first peak and the second peak is 4 nm to 20 nm.

12. The light emitting display device according to claim 11, wherein the first peak has a wavelength of 510 nm to 550 nm.

14. The light emitting display device according to claim 11, wherein the first light emitting elements and the second light emitting elements are alternately disposed in a row, in a column, or in a diagonal direction.

15. The light emitting display device according to claim 11, wherein, when the first and second light emitting elements are driven with a current of 10 mA/cm² or less, a larger number of the first light emitting elements than the second light emitting elements are turned on.

16. The light emitting display device according to claim 11, wherein
each of the first to fourth light emitting elements has an anode and a cathode opposite each other,
each of the first and second light emitting elements comprises at least one first emission layer provided between the anode and the cathode, the first emission layer being configured to emit the first color of light,
each of the third light emitting elements comprises at least one second emission layer provided between the anode and the cathode, the second emission layer being configured to emit the second color of light, and
each of the fourth light emitting elements comprises at least one third emission layer provided between the anode and the cathode, the third emission layer being configured to emit the third color of light.
